(19) United States
(12) Patent Application Publication
(10) Pub. No.: US 2024/0363331 A1
(43) Pub. Date: Oct. 31, 2024

(54) SUBSTRATE SUPPORT PLATE, SUBSTRATE PROCESSING APPARATUS INCLUDING THE SAME, AND SUBSTRATE PROCESSING METHOD

(71) Applicant: ASM IP Holding B.V., Almere (NL)

(72) Inventors: DaeYoun Kim, Seo-gu (KR); JaeHyun Kim, Hwaseong-si (KR); SeungHwan Lee, Anseong-si (KR)

(21) Appl. No.: 18/664,118

(22) Filed: May 14, 2024

Related U.S. Application Data
(63) Continuation of application No. 17/120,063, filed on Dec. 11, 2020.
(60) Provisional application No. 62/947,475, filed on Dec. 12, 2019.

(51) Int. Cl. H01L 21/02; C23C 16/455; C23C 16/458; H01J 37/20; H01J 37/32

(52) U.S. Cl. CPC H01L 21/02087; C23C 16/45536; C23C 16/45544; C23C 16/4586; H01J 37/20; H01J 37/3244; H01J 37/32715

(57) ABSTRACT

A substrate processing apparatus capable of selective processing a thin film in a bevel edge includes: a substrate support plate including a recess and at least one path formed in the recess; and a gas supply unit on the substrate support plate, wherein a first distance between a portion of the substrate support plate inside the recess and the gas supply unit is less than a second distance between the gas supply unit and the other portion of the substrate support plate outside the recess.

### CROSS-REFERENCE TO RELATED APPLICATION

This application is a divisional of, and claims priority to, U.S. patent application Ser. No. 17/120,063 filed December 2020 titled SUBSTRATE SUPPORT PLATE, SUBSTRATE PROCESSING APPARATUS INCLUDING THE SAME, AND SUBSTRATE PROCESSING METHOD; which is based on and claims priority under 35 U.S.C. § 119 to U.S. Patent Application No. 62/947,475 filed on Dec. 12, 2019, in the United States Patent and Trademark Office, the disclosures of which are incorporated by reference herein in their entirety.

### BACKGROUND

### 1. Field

One or more embodiments relate to a substrate support plate, and more particularly, to a substrate support plate, a substrate processing apparatus including the substrate support plate, and a substrate processing method using the substrate support plate.

### 2. Description of Related Art

In a semiconductor device manufacturing process, a substrate surface is planarized while a chemical mechanical polishing (CMP) process is performed after a through-silicon via (TSV) process. However, during this process, there is a problem that a film deposited on a bevel edge of a substrate edge is lost more quickly. The lost film may act as a contaminant in a reactor and make it difficult to utilize the substrate edge.

FIG. 1 shows a SiO₂ thin film deposited on a substrate for the TSV process. FIG. 1A shows the deposition of SiO₂ film on the substrate, and FIG. 1B shows the loss of the SiO₂ film at a bevel edge of a substrate edge after the CMP process. The lost portion is indicated by a dashed line.

Since the TSV process includes a process of stacking a plurality of substrates, the adhesion between the substrates is important for the TSV process to be performed smoothly. However, as described above, when the SiO₂ film is lost at the bevel edge of the substrate edge, the adhesion between the substrates becomes weak.

### SUMMARY

One or more embodiments include a deposition apparatus and a method thereof for recovering the thickness of a thin film lost at a bevel edge of a substrate edge.

One or more embodiments include a deposition apparatus and a method thereof for preventing thin film deposition on a lower surface of a substrate that may occur when forming a thin film on a bevel edge of a substrate edge.

Additional aspects will be set forth in part in the description which follows and, in part, will be apparent from the description, or may be learned by practice of the presented embodiments of the disclosure.

According to one or more embodiments, a substrate support plate, which is configured to support a substrate to be processed, includes: an inner portion having an upper surface less than the area of the substrate to be processed; a first step formed by a side surface of the inner portion; and a second step surrounding the first step, wherein at least one path may be formed on an upper surface of the substrate support plate between the first step and the second step.

According to an example of the substrate support plate, the distance from the center of the substrate support plate to the second step may be less than the radius of the substrate to be processed.

According to an example of the substrate support plate, the substrate support plate may further include a recess formed by the first step and the second step, and the at least one path may be formed in the recess.

According to another example of the substrate support plate, the substrate support plate may further include a third step formed outside the recess.

According to another example of the substrate support plate, at least a portion of the upper surface of the substrate support plate outside the path may be below the upper surface of the inner portion.

According to another example of the substrate support plate, an upper surface of the second step outside the path may be below an upper surface of the first step inside the path.

According to another example of the substrate support plate, the substrate support plate may further include a third step formed outside the second step, and a lower surface of the third step may be below the upper surface of the inner portion.

According to one or more embodiments, a substrate processing apparatus includes: a substrate support plate including a recess and at least one path formed in the recess; and a gas supply unit on the substrate support plate, wherein a first distance between the gas supply unit and a portion of the substrate support plate inside the recess may be less than a second distance between the gas supply unit and the other portion of the substrate support plate outside the recess.

According to an example of the substrate processing apparatus, the gas supply unit may include a plurality of injection holes, and the plurality of injection holes may be distributed over the area of an upper surface of the substrate support plate or more extending from the center of the substrate support plate to the recess.

According to another example of the substrate processing apparatus, the plurality of injection holes may be distributed over the area of the substrate to be processed or more.

According to another example of the substrate processing apparatus, the substrate processing apparatus may supply a first gas through the gas supply unit, and supply a second gas different from the first gas through the path.

According to another example of the substrate processing apparatus, a reaction space may be formed between the substrate support plate and the gas supply unit, and the reaction space may include a first reaction space between the gas supply unit and a portion of the substrate support plate inside the recess; and a second reaction space between the gas supply unit and the other portion of the substrate support plate outside the recess.

According to another example of the substrate processing apparatus, plasma may be generated by supplying power between the gas supply unit and the substrate support plate, and the plasma of the first reaction space may be less than the plasma of the second reaction space.

According to another example of the substrate processing apparatus, the upper surface of the substrate support plate outside the recess may be below the upper surface of the substrate support plate inside the recess, and the second reaction space may extend from the upper surface of the substrate support plate outside the recess to the gas supply unit.

According to another example of the substrate processing apparatus, the substrate support plate may further include a third step formed outside the recess, and the second reaction space may extend from the upper surface of the substrate support plate outside the third step to the gas supply unit.

According to another example of the substrate processing device, the substrate support plate may further include a protrusion formed between the recess and the third step.

According to another example of the substrate processing apparatus, an upper surface of the third step may be disposed to correspond to an edge region of the substrate to be processed.

According to another example of the substrate processing apparatus, the substrate support plate may further include at least one pad on the upper surface of the substrate support plate inside the recess, and the upper surface of the third step may be below an upper surface of the pad.

According to another example of the substrate processing apparatus, the gas supply unit may include a step, and the second reaction space may extend from the upper surface of the substrate support plate outside the recess to the step of the gas supply unit.

According to one or more embodiments, a substrate processing method includes: mounting a substrate to be processed on a substrate support plate of the substrate processing apparatus described above; supplying a first gas through the gas supply unit and supplying a second gas through the path; generating plasma by supplying power between the gas supply unit and the substrate support plate; and forming a thin film on an edge region of the substrate to be processed using the plasma, wherein during the generating of the plasma, plasma in a first space between the gas supply unit and a portion of the substrate support plate inside the recess may be less than plasma in a second space between the gas supply unit and the other portion of the substrate support plate outside the recess.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1A and 1B show a SiO₂ thin film deposited on a substrate;

FIGS. 2A, 2B, and 2C are views of a substrate support plate according to embodiments of the inventive concept;

FIGS. 3A, 3B, and 3C are views of a substrate support plate according to embodiments of the inventive concept;

FIG. 4 is a view of a substrate processing apparatus according to embodiments of the inventive concept;

FIG. 5 is a view showing a substrate processing method according to embodiments of the inventive concept;

FIG. 6 is a view of a substrate processing apparatus according to embodiments of the inventive concept;

FIG. 7 is a view of a substrate processing apparatus according to embodiments of the inventive concept;

FIG. 8 is a view of a substrate processing apparatus according to embodiments of the inventive concept;

FIG. 9 is a view of a substrate processing apparatus according to embodiments of the inventive concept;

FIG. 10 is a partial enlarged view of the substrate processing apparatus of FIG. 9;

FIGS. 11A and 11B are detailed views of a susceptor according to FIG. 10;

FIG. 12 is a view of a substrate processing apparatus according to embodiments of the inventive concept;

FIGS. 13A and 13B are oblique cross-sectional views of a susceptor of FIG. 12;

FIG. 14 is a view of a substrate processing apparatus according to embodiments of the inventive concept;

FIGS. 15A and 15B illustrate examples of a process for forming a thin film;

FIG. 16 is a view of a thickness of a SiO₂ thin film deposited on a bevel edge of a substrate when the process of FIG. 15B is applied; and

FIG. 17 is a view of a photograph of a film deposited in a 1 mm area of a bevel edge of an actual substrate edge.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments of the disclosure will be described in detail with reference to the accompanying drawings.

In this regard, the present embodiments may have different forms and should not be construed as being limited to the descriptions set forth herein. Rather, these embodiments are provided so that the present disclosure will be thorough and complete, and will fully convey the scope of the present disclosure to one of ordinary skill in the art.

The terminology used herein is for the purpose of describing particular embodiments and is not intended to limit the disclosure. As used herein, the singular forms “a”, “an”, and “the” are intended to include the plural forms as well, unless the context clearly indicates otherwise. It will be further understood that the terms “includes”, “comprises” and/or “including”, “comprising” used herein specify the presence of stated features, integers, steps, operations, members, components, and/or groups thereof, but do not preclude the presence or addition of one or more other features, integers, steps, operations, members, components, and/or groups thereof. As used herein, the term “and/or” includes any and all combinations of one or more of the associated listed items.

It will be understood that, although the terms first, second, etc. may be used herein to describe various members, components, regions, layers, and/or sections, these members, components, regions, layers, and/or sections should not be limited by these terms. These terms do not denote any order, quantity, or importance, but rather are only used to distinguish one component, region, layer, and/or section from another component, region, layer, and/or section. Thus, a first member, component, region, layer, or section discussed below could be termed a second member, component, region, layer, or section without departing from the teachings of embodiments.

Embodiments of the disclosure will be described hereinafter with reference to the drawings in which embodiments of the disclosure are schematically illustrated. In the drawings, variations from the illustrated shapes may be expected as a result of, for example, manufacturing techniques and/or tolerances. Thus, the embodiments of the disclosure should not be construed as being limited to the particular shapes of regions illustrated herein but may include deviations in shapes that result, for example, from manufacturing processes.

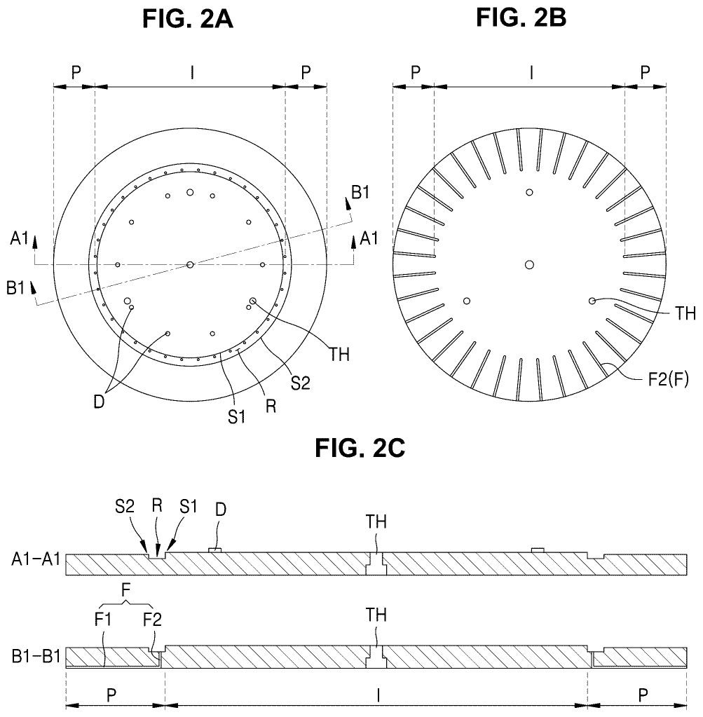

FIG. 2 is a view of a substrate support plate according to embodiments of the inventive concept. FIG. 2A is a plan view of the substrate support plate, FIG. 2B is a rear view of the substrate support plate, and FIG. 2C is a cross-sectional view of the substrate support plate taken along line A-A and line B-B.

Referring to FIG. 2, the substrate support plate is a configuration for supporting a substrate to be processed, and the substrate to be processed may be seated on the substrate support plate. The substrate support plate may include an inner portion I, a peripheral portion P, and at least one pad D. In addition, a path F and a through hole TH may be formed in the substrate support plate.

The inner portion I may be defined as a central region of the substrate support plate. The inner portion I may be formed to have an upper surface less than the area of the substrate to be processed. An upper surface of the inner portion I may have a shape corresponding to the shape of the substrate to be processed. For example, when the substrate to be processed is a circular substrate having a first diameter, the inner portion I may have a circular upper surface having a second diameter that is less than the first diameter.

The peripheral portion P may be formed to surround the inner portion I. For example, when the inner portion I is a plate-like structure having a circular upper surface, the peripheral portion P may be a ring-shaped configuration that surrounds this plate-like structure. In an embodiment, a first step S1 may be formed between the peripheral portion P and the inner portion I. The first step S1 may be formed by a side surface of the inner portion I. In addition, a second step S2 may be formed in the peripheral portion P. The second step S2 may be formed to surround the first step S1.

A recess R may be formed by the first step S1 and the second step S2. That is, the recess R may be defined by a side surface of the first step S1 (i.e., the side surface of the inner portion I), an upper surface of a substrate support plate below the upper surface of the inner portion I, and a side surface of the second step S2. The recess R may function a buffer holding a gas supplied between the substrate to be processed and the substrate support plate.

At least one pad D may be on the inner portion I. For example, the at least one pad D may be plural, and the plurality of pads D may be symmetrically arranged with respect to the center of the substrate support plate. The substrate to be processed may be seated on the substrate support plate to be in contact with the at least one pad D. In an example, the at least one pad D may be configured to prevent horizontal movement of the substrate to be processed seated on the substrate support plate. For example, the at least one pad D may include a material having a certain roughness, and the roughness of the material may prevent slippage of the substrate to be processed.

The peripheral portion P may include at least one path F. For example, the at least one path F may be formed between the first step S1 and the second step S2. As a specific example, the at least one path F may be formed on an upper surface of the substrate support plate between the first step S1 and the second step S2. In more detail, the at least one path F may be formed in the recess R formed by the first step S1 and the second step S2.

The path F may extend from a portion of the peripheral portion toward the other portion of the peripheral portion. In another example, the path F may extend from a portion of the peripheral portion toward a portion of the inner portion I. In other words, the fact that the at least one path F is formed between the first step S1 and the second step S2 means that at least one end portion of the path F is formed between the first step S1 and the second step S2.

In an example where the path F extends from one portion of the peripheral portion P to the other portion of the peripheral portion P, the path F may be formed to penetrate the substrate support plate between the first step S1 and the second step S2. In an alternative example, the path F may include a first portion F1 extending from a side surface of the substrate support plate toward the peripheral portion P and a second portion F2 extending from the peripheral portion P toward the upper surface of the substrate support plate.

The path F may function as a moving path of gas. For example, an inert gas (e.g., argon) or a highly stable gas (e.g., oxygen) may be supplied through the path F. The gas is supplied through the path F while an upper surface of the peripheral portion P is disposed below the upper surface of the inner portion I, whereby partial processing of a thin film on an edge region (e.g., bevel edge) of the substrate to be processed seated on the substrate support plate may be achieved.

In an example, a distance from the center of the substrate support plate to the second step S2 may be less than the radius of the substrate to be processed. Therefore, when the substrate to be processed is seated on the substrate support plate, a channel may be formed between the second step S2 and the substrate to be processed. The gas supplied through the path F formed in the recess R may move to a reaction space through the channel formed between the substrate to be processed and the second step S2.

The path F may include a plurality of paths. In an example, the plurality of paths may be symmetrically arranged with respect to the center of the substrate support plate. Also, the plurality of paths may extend to face a rear surface of the substrate to be processed. For example, a distance from the center of the substrate support plate to the path F of the peripheral portion P may be less than the radius of the substrate to be processed. Therefore, the gas may be uniformly supplied onto the rear surface of the substrate to be processed seated on the substrate support plate through the plurality of symmetrically arranged paths.

The upper surface of the substrate support plate may have different levels. For example, based on the path F, at least a portion of the upper surface of the substrate support plate outside the path F (e.g., outside the second step S2) may be below the upper surface of the substrate support plate inside the path F (e.g., inside the first step S1). In more detail, an upper surface of the second step S2 outside the path F may be below an upper surface of the first step S1 inside the path F.

By such surface arrangement of the substrate support plate, partial processing for an edge region (e.g., bevel edge) of the substrate to be processed may be achieved. A reaction space is formed between the substrate support plate and the gas supply unit when the substrate support plate is face-sealed with a reactor wall of a substrate processing apparatus described later below. In this case, since the substrate support plate has different levels of upper surfaces for each position, a reaction space with different heights may be formed, thereby generating different amounts of plasma for each position of the reaction space.

The through hole TH may be formed in the inner portion I. The through hole TH (of FIGS. 2 (a) and (b)) formed in the inner portion I may provide a space in which a substrate support pin used to move the substrate when the substrate is mounted moves. In addition, a fixing pin (not shown) for fixing the position of the substrate support plate may be inserted into the through hole (of FIG. 2 (c)) located at the center of the inner portion I. In this respect, the through hole TH is distinguished from the path F used as a moving path of the gas. For example, the through hole TH may be formed to have a diameter different from that of the path F.

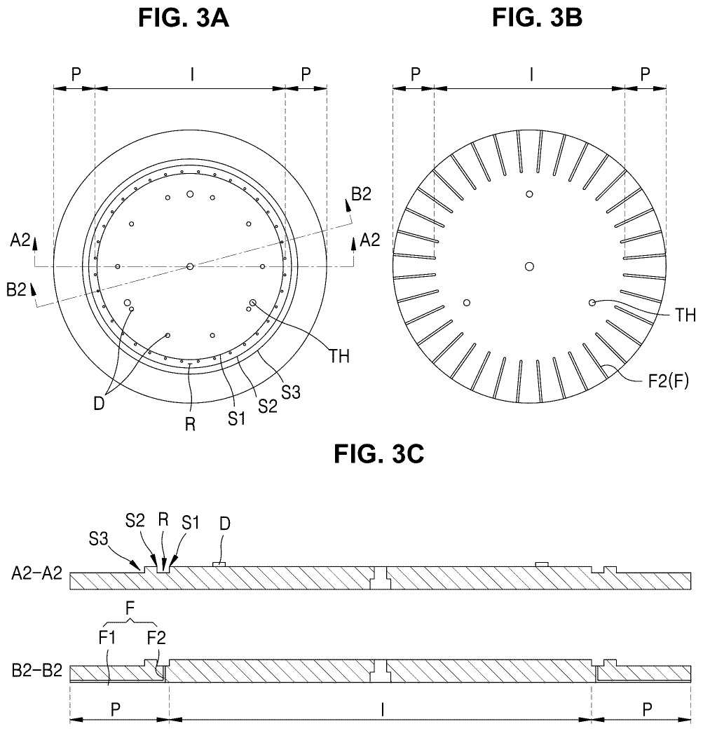

FIG. 3 is a view of a substrate support plate according to embodiments of the inventive concept. FIG. 3A is a plan view of the substrate support plate, FIG. 3B is a bottom view of the substrate support plate, and FIG. 3C is a cross-sectional view of the substrate support plate taken along line A2-A2 and line B2-B2.

Referring to FIG. 3, the substrate support plate may further include a third step S3. The third step S3 may be formed outside the second step S1. The third step S3 may be formed outside the recess R formed by the first step S1 and the second step S2.

A lower surface of the third step S3 may be below an upper surface of the inner portion I. When the substrate support plate is face sealed with a reactor wall of the substrate processing apparatus to form a reaction space, the reaction space may include a first reaction space between the gas supply device and the upper surface of the inner portion and a second reaction space between the gas supply device and the lower surface of the third step S3.

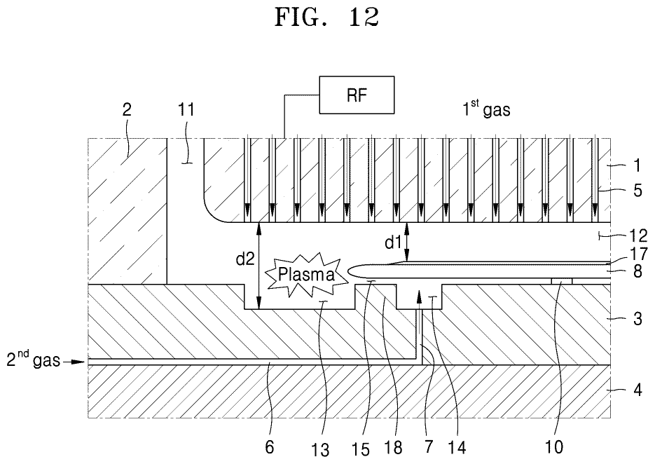

In some embodiments, the inner portion I of the substrate support plate 103 may protrude from the peripheral portion P of the substrate support plate 103, and thus the inner portion I may form a convex portion of the substrate support plate 103. Further, in some embodiments, although not shown in the drawings, a portion of the substrate support plate 103 face sealing with a reactor wall 101 may protrude from an upper surface of the peripheral portion P, thereby forming a concave portion in the peripheral portion P of the substrate support plate 103. Due to the convex structure of the peripheral portion P, an additional recess may be formed outside the recess R (see FIG. 12).

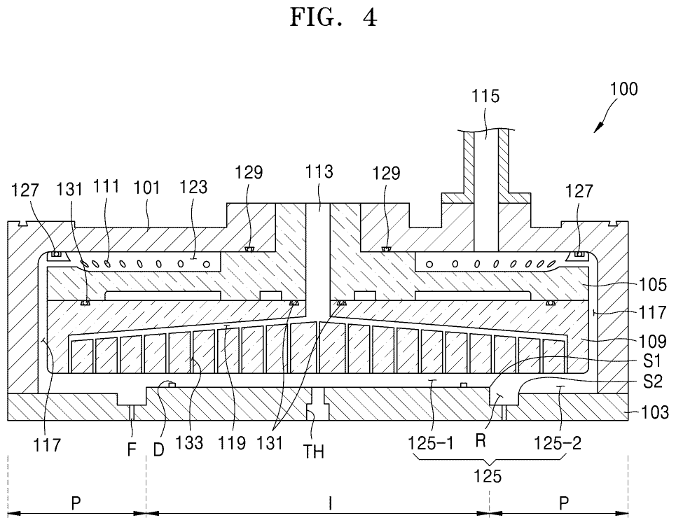

FIG. 4 is a view of a substrate processing apparatus according to embodiments of the inventive concept. The substrate processing apparatus according to these embodiments may include at least some of the features of a substrate support plate according to the above-described embodiments. Hereinafter, repeated descriptions of the embodiments will not be given herein.

FIG. 4 shows a cross-section of a semiconductor processing apparatus 100. The semiconductor processing apparatus 100 may include the substrate support plate 103 and a gas supply unit 109 on the substrate support plate 103.

The gas supply unit 109 may include a plurality of injection holes 133. The plurality of injection holes 133 may be formed to face the inner portion I of the substrate support plate 103. In an example, the plurality of injection holes 133 may be distributed over at least the area of the upper surface of the substrate support plate (i.e., the upper surface of the inner portion I) extending from the center of the substrate support plate 103 to the recess R. In some examples, the plurality of injection holes 133 may be distributed over the area of the substrate to be processed or more. Such a distribution shape of the injection holes 133 may contribute to facilitating partial processing (e.g., deposition) of a thin film on an edge region of the substrate to be processed.

A first gas may be supplied through the plurality of injection holes 133 of the gas supply unit 109. In addition, as described above, a second gas different from the first gas may be supplied through the path F of the substrate support plate 103. The first gas may include a material used to deposit a thin film on the substrate to be processed. The second gas may include a material reactive with the first gas. The first gas and/or the second gas may include an inert gas (e.g., argon) or a highly stable gas (e.g., nitrogen).

The substrate support plate 103 may include at least some of the configurations of the substrate support plate 103 according to the above-described embodiments. For example, the substrate support plate 103 may include the inner portion I having an upper surface of an area less than that of the substrate to be processed and the peripheral portion P surrounding the inner portion I. In addition, the substrate support plate 103 may include the first step S1, the second step S2, and the path F between the first step S1 and the second step S2. In addition, as described above, the substrate support plate 103 may include the recess R formed by the first step S1 and the second step S2, and the path F may be formed in the recess R.

The upper surface of a portion of the substrate support plate 103 inside the recess R may be above the upper surface of the other portion of the substrate support plate 103 outside the recess R. Therefore, a first distance between the gas supply unit 109 and the portion of the substrate support plate inside the recess R may be less than a second distance between the gas supply unit 109 and the other portion of the substrate support plate outside the recess R.

According to some examples, when the substrate to be processed is mounted on the inner portion I, a distance between the substrate to be processed and the gas supply unit 109 may be about 2 mm or less, and the second distance between the peripheral portion P and the gas supply unit 109 may be about 3 mm or more. As such, by forming a sufficient distance between the peripheral portion P and the gas supply unit 109, partial processing of the thin film on the edge region of the substrate to be processed seated on the substrate support plate 103 may be achieved.

Among the above-described embodiments, when a lower surface of the gas supply unit 109 is flat and a difference between the first distance and the second distance is realized, further technical advantages may be achieved. In more detail, when a first lower surface of the gas supply unit 109 in a region where the plurality of injection holes are distributed is on one plane (see FIG. 4), the distance between the substrate to be processed and the gas supply unit 109 may be constant.

In this case, a distance between the upper surface of the substrate to be processed and the first lower surface and a distance between the upper surface of the substrate to be processed and the second lower surface are constant. As a result, processing of the thin film on the edge region of the substrate to be processed between the peripheral portion P and the gas supply unit 109 may be performed without a separate alignment operation. For example, by adjusting a flow rate ratio of the first gas supplied through the gas supply unit 109 and the second gas supplied through the at least one path F, processing (e.g., deposition) of the thin film on the edge region of the substrate to be processed in an unaligned state may be performed.

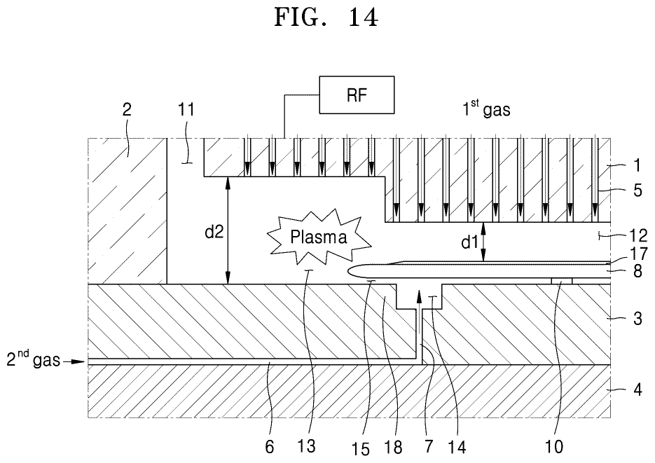

Meanwhile, when the lower surface of the gas supply unit 109 in an area where the plurality of injection holes are distributed is on two or more planes, that is, when the lower surface of the gas supply unit 109 includes lower surfaces of different levels (see, e.g., FIG. 14), the degree of processing (e.g., formation) of the thin film on the edge region of the substrate to be processed may be affected by the distance between the thin film and the lower surface of the gas supply unit 109. Thus, in such a case, an alignment form of the substrate to be processed on the substrate support plate 103 will affect symmetry of the processing of the thin film on the edge region of the substrate to be processed.

In the semiconductor processing apparatus 100, the reactor wall 101 may be in contact with the substrate support plate 103. In more detail, a reaction space 125 may be formed between the substrate support plate 103 and the gas supply unit 109 while a lower surface of the reactor wall 101 is in contact with the substrate support plate 103 serving as a lower electrode. The reaction space 125 may include a first reaction space 125-1 between the gas supply unit 109 and a portion of the substrate support plate inside the recess R (e.g., the inner portion I), and a second reaction space 125-2 between the gas supply unit 109 and the other portion of the substrate support plate outside the recess R (e.g., the peripheral portion P).

In some embodiments, the height of the second reaction space 125-2 may be greater than the height of the first reaction space 125-1. In more detail, the upper surface of the substrate support plate outside the recess R may be below the upper surface of the substrate support plate inside the recess R. Accordingly, the second reaction space 125-2 may extend from the upper surface of the substrate support plate outside the recess R to the gas supply unit 109. The height of the second reaction space 125-2 may be greater than the height of the first reaction space 125-1.

In some embodiments, the first reaction space 125-1 may be configured to process a thin film on a central region of the substrate to be processed. The second reaction space 125-2 may be configured to process a thin film on the edge region of the substrate to be processed. For example, in order to process the thin film on the substrate, power may be supplied between the gas supply unit 109 and the substrate support plate 103, and plasma may be generated in the second reaction space 125-2 by the power supply. In some additional examples, plasma may be generated in the first reaction space 125-1 and the second reaction space 125-2 by the power supply.

As described above, since a distance between the substrate support plate 103 and the gas supply unit 109 in the first reaction space 125-1 is less than the distance between the substrate support plate 103 and the gas supply unit 109 in the second reaction space 125-2, less plasma may be formed in the first reaction space 125-1 with a less distance by Paschen's law. In other words, the plasma of the first reaction space 125-1 may be less than the plasma of the second reaction space 125-2. In the present specification, it should be noted that the plasma in the first reaction space 125-1 is less than the plasma in the second reaction space 125-2 includes a case where plasma is formed in the second reaction space 125-2 and no plasma is formed in the first reaction space 125-1.

The substrate support plate 103 may be configured to face seal with the reactor wall 101. The reaction space 125 may be formed between the reactor wall 101 and the substrate support plate 103 by the face sealing. In addition, a gas exhaust path 117 may be formed between a gas flow control device 105 and the gas supply unit 109 and the reactor wall by the face sealing.

The gas flow control device 105 and the gas supply unit 109 may be disposed between the reactor wall 101 and the substrate support plate 103. The gas flow control device 105 and the gas supply unit 109 may be integrally formed, or may be configured in a separate type in which portions having injection holes 133 are separated. In the separate structure, the gas flow control device 105 may be stacked on the gas supply unit 109. Optionally, the gas supply unit 109 may also be configured separately, in which case the gas supply unit 109 may include a gas injection device having a plurality of through holes and a gas channel stacked on the gas injection device.

The gas flow control device 105 may include a plate and a sidewall 123 protruding from the plate. A plurality of holes 111 penetrating a side wall 123 may be formed in the side wall 123.

Grooves 127, 129, and 131 for accommodating a sealing member such as an O-ring may be formed between the reactor wall 101 and the gas flow control device 105 and between the gas flow control device 105 and the gas supply unit 109. By the sealing member, an external gas may be prevented from entering the reaction space 125. In addition, by the sealing member, a reaction gas in the reaction space 125 may exit along a designated path (i.e., the gas exhaust path 117 and a gas outlet 115, see FIG. 4). Therefore, the outflow of the reaction gas into a region other than the designated path may be prevented.

The gas supply unit 109 may be used as an electrode in a plasma process such as a capacitively coupled plasma (CCP) method. In this case, the gas supply unit 109 may include a metal material such as aluminum (Al). In the CCP method, the substrate support plate 103 may also be used as an electrode, so that capacitive coupling may be achieved by the gas supply unit 109 serving as a first electrode and the substrate support plate 103 serving as a second electrode.

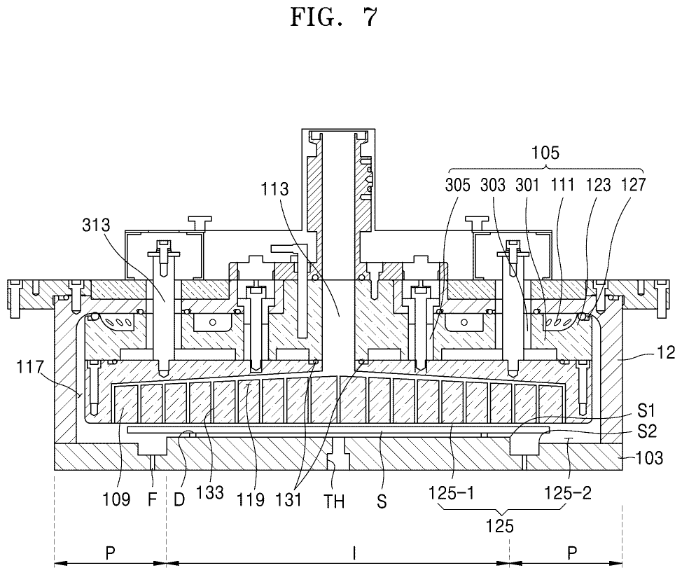

In more detail, plasma generated in an external plasma generator (not shown) may be transmitted to the gas supply unit 109 by an RF rod 313 (of FIG. 7). The RF rod 313 may be mechanically connected to the gas supply unit 109 through an RF rod hole 303 (of FIG. 7) penetrating an upper portion of the reactor wall 101 and the gas flow control device 105.

Optionally, the gas supply unit 109 is formed of a conductor while the gas flow control device 105 includes an insulating material such as ceramics so that the gas supply unit 109 used as a plasma electrode may be insulated from the reactor wall 101.

As shown in FIG. 4, a gas inlet 113, which penetrates the reactor wall 101 and the central portion of the gas flow control device 105, is formed in an upper portion of the reactor wall 101. In addition, a gas flow path 119 is further formed in the gas supply unit 109, and thus, a reaction gas supplied through the gas inlet 113 from an external gas supply unit (not shown) may be uniformly supplied to each of the injection holes 133 of the gas supply unit 109.

In addition, as shown in FIG. 4, the gas outlet 115 is disposed at the top of the reactor wall 101 and asymmetrically with respect to the gas inlet 113. Although not shown in the drawings, the gas outlet 115 may be disposed symmetrically with respect to the gas inlet 113. In addition, the reactor wall 101 and a sidewall of the gas flow control device 105 (and a sidewall of the gas supply unit 109) are apart from each other, and thus the gas exhaust path 117 through which a residual gas of the reaction gas is exhausted may be formed after the process proceeds.

In an alternative embodiment, the gas supply unit 109 may be formed to have a step (see FIG. 14). In more detail, the lower surface of the gas supply unit 109 shown in FIG. 4, that is, the surface facing the substrate to be processed, is illustrated to be flat without bending. However, according to the alternative embodiment, the lower surface of the gas supply unit 109 may be formed to have a bend. For example, a step may be formed at an edge portion of the gas supply unit 109, and the lower surface of the gas supply unit 109 outside the step may be above the lower surface of the gas supply unit 109 inside the step.

Due to the location of the edge portion of the gas supply unit 109 on the lower surface of the gas supply unit 109, the height of the second reaction space 125-2 may be further extended. That is, outside the recess R, the second reaction space 125-2 may extend from the upper surface of the substrate support plate to the step of the gas supply unit 109. As a result, by the above configuration, the function of allowing plasma not to be formed in the first reaction space 125-1 adjacent to the center of the gas supply unit 109 and allowing plasma to be formed in the second reaction space 125-2 adjacent to the edge of the gas supply unit 109 may be promoted.

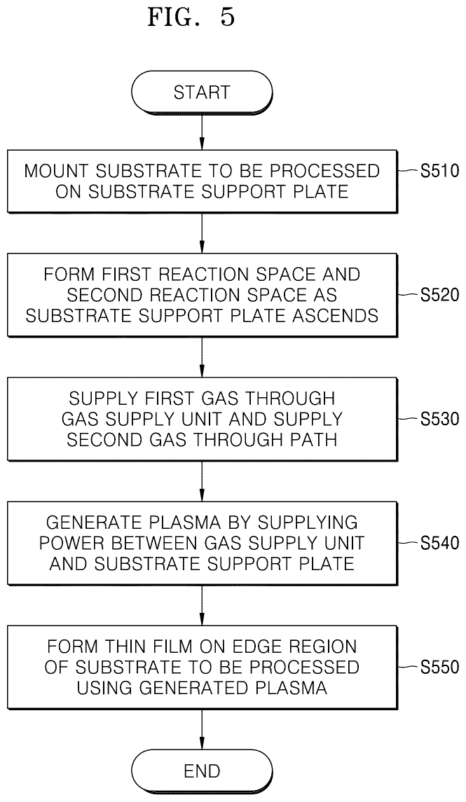

FIG. 5 is a view showing a substrate processing method according to embodiments of the inventive concept. The substrate processing method according to the embodiments may be performed using the substrate support plate and the substrate processing apparatus according to the above-described embodiments. Hereinafter, repeated descriptions of the embodiments will not be given herein.

Referring to the drawings (e.g., FIG. 4) of the substrate processing apparatus and FIG. 5, in operation S510, a substrate to be processed is first mounted on the substrate support plate 103. For example, the substrate support plate 103 descends and a substrate support pin ascends through a through hole. The substrate to be processed is then transmitted from a robot arm onto the substrate support pin. The substrate support pin then descends and the substrate to be processed is seated onto an inner portion of the substrate support plate 103.

Thereafter, in operation S520, the substrate support plate 103 ascends to form the first reaction space 125-1 and the second reaction space 125-2. For example, the substrate support plate may be face sealed with a reactor wall of the substrate processing apparatus to form a reaction space. The first reaction space 125-1 may be defined as a space between the gas supply unit 109 and a portion of the substrate support plate inside the recess R, and the second reaction space 125-2 may be defined as a space between the gas supply unit 109 and the other portion of the substrate support plate outside the recess R.

In operation S530, after the reaction space is formed, the first gas is supplied through the gas supply unit 109, and the second gas is supplied through a path. In some embodiments, the first gas may include a material (e.g., a silicon precursor) to form a thin film, and the second gas may be a material (e.g., oxygen) that is reactive with the first gas when energy is applied thereto. In another example, the first gas may include a material for forming a thin film, and the second gas may include an inert gas.

In operation S540, in a state where the first gas and the second gas are supplied, power is supplied between the gas supply unit 109 on the substrate support plate 103 and the substrate support plate 103 to generate plasma. In this case, the upper surface of a portion of the substrate support plate (i.e., the inner portion of the substrate support plate 103) inside the recess R may be disposed on the upper surface of the other portion of the substrate support plate (i.e., a peripheral portion of the substrate support plate 103) outside the recess R. Therefore, a first distance between the inner portion and the gas supply unit 109 may be less than a second distance between the peripheral portion and the gas supply unit 109. As a result, while the amount of radicals generated in the first reaction space 125-1 with a less distance between the inner portion of the substrate support plate 103 and the gas supply unit 109 is relatively small or absent, the amount of radicals generated in the second reaction space 125-2 with a large distance between the peripheral portion of the substrate support plate 103 and the gas supply unit 109 will be relatively large.

In operation S550, the generated plasma is used to form a thin film on the edge region of the substrate to be processed. For example, a first gas and a second gas are supplied to the reaction space 125 through the gas supply unit 109, and then the second gas is ionized by a potential difference formed between the gas supply unit 109 and the substrate support plate 103 to generate a radical. The radical may be reactive with the first gas, and a thin film may be formed on the substrate by the reaction of the first gas and the radical.

In another example, during operations S540 and S550, a first gas is supplied through the gas supply unit 109, and a second gas reactive with the first gas is supplied to the reaction space 125 through the path F. The second gas is then ionized by the potential difference formed between the gas supply unit 109 and the substrate support plate 103 to generate a radical. The radical may be reactive with the first gas, and a thin film may be formed on the substrate by the reaction of the first gas and the second gas.

As mentioned above, during the generating of the plasma, plasma in the first space between the gas supply unit 109 and a portion of the substrate support plate inside the recess R may be less than plasma in a second space between the gas supply unit 109 and the other portion of the substrate support plate outside the recess R. In other words, since radicals are relatively formed in the peripheral portion of the substrate support plate 103, most of the thin film may be formed in the edge region of the substrate to be processed.

As such, according to embodiments of the inventive concept, thin film deposition on an inclined surface of a substrate edge, such as a bevel edge, may be achieved. That is, by forming a sufficient distance between the peripheral portion of the substrate support plate and the gas supply unit, partial processing (e.g., deposition) of the thin film on the edge region of the substrate to be processed seated on the substrate support plate may be achieved.

Furthermore, according to embodiments of the inventive concept, by supplying a gas to a buffer region under the substrate through a gas inlet and a vertical through hole formed on the side of the susceptor, and by forming a gas barrier in a gap between a lower surface of the substrate and an upper surface of the susceptor, a thin film may be selectively deposited on the side and upper portions of a bevel edge while preventing a thin film from being deposited on the lower surface of the bevel edge.

In addition, according to embodiments of the inventive concept, regardless of whether or not the substrate is aligned on the substrate support plate, a thin film may be deposited on the bevel edge symmetrically with a uniform width along the bevel edge of the substrate. For example, a thin film processing region in the bevel edge of the substrate may be controlled according to the conditions of applied RF power, and selective formation of the thin film of the bevel edge of the substrate may be achieved without an alignment operation of the substrate.

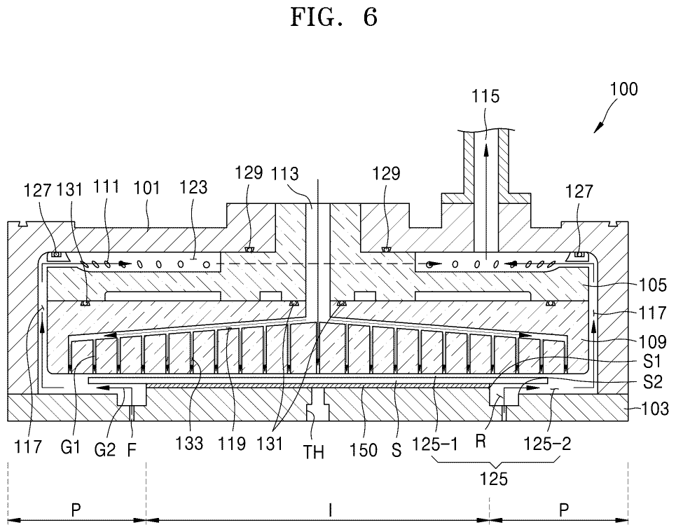

FIG. 6 is a view of a substrate processing apparatus according to embodiments of the inventive concept. The substrate processing apparatus according to the embodiments may be a variation of the substrate processing apparatus according to the above-described embodiments. Hereinafter, repeated descriptions of the embodiments will not be given herein.

Referring to FIG. 6, a first gas G1 and a second gas G2 may be supplied to the reaction space 125 of the semiconductor processing apparatus. For example, the first gas G1 may include a component (e.g., a precursor) used to form a thin film on a substrate S to be processed. The first gas G1 may be supplied through an injection hole 133 of the gas supply unit 109. In addition, the first gas G1 may be supplied toward an upper surface of the substrate S to be processed (i.e., the surface on which the thin film is formed). For example, the first gas G1 may be uniformly supplied over the entire area of the substrate S to be processed. In another example, the first gas G1 may be non-uniformly supplied toward an edge region of the substrate S to be processed.

The second gas G2 may include a component different from the first gas G1. In an alternative embodiment, the second gas G2 may include a component that is reactive with the first gas G1. In another alternative embodiment, the second gas G2 may include an inert gas. The second gas G2 may be supplied through the path F of the substrate support plate 103. In addition, the second gas G2 may be supplied toward a rear surface of the substrate S to be processed, and the second gas G2 may be supplied toward the edge region of the substrate S to be processed.

As described above, the reaction space 125 may include the first reaction space 125-1 and the second reaction space 125-2. When power is applied, a relatively small amount of plasma is generated or no plasma is generated in the first reaction space 125-1 between the inner portion I and the gas supply unit 109. However, a relatively large amount of plasma may be generated in the second reaction space 125-2 between the peripheral portion P and the gas supply units 109.

Therefore, in the second reaction space 125-2 in which a relatively large amount of plasma is generated, a reaction between the first gas G1 and the second gas G2 may be promoted. As a result, a chemical reaction on the edge region of the substrate S to be processed may be performed, and the thin film on the edge region of the substrate S to be processed may be formed.

A residual gas after forming the thin film on the edge region is transmitted to the gas flow control device 105 through the gas exhaust path 117 formed between the reactor wall 101 and a side wall of the gas supply unit 109. The gas transmitted to the gas flow control device 105 may be introduced into an internal space of the gas flow control device 105 through the through holes 111 formed in the side wall 123 and then exhausted to the outside through the gas outlet 115.

In an alternative embodiment, at least a portion of the inner portion I of the substrate support plate 103 may be anodized. By the anodizing, an insulating layer 150 may be formed on at least a portion of the upper surface of the inner portion I. For example, the insulating layer 150 may include aluminum oxide. By an anodizing process, adhesion of a substrate may be achieved by electrostatic force.

FIG. 7 is a cross-sectional view of a semiconductor processing apparatus according to the disclosure seen from another cross-section. Referring to FIG. 7, the gas flow control device 105 includes the side wall 123, the gas inlet 113, a plate 301 surrounded by the side wall 123, the RF rod hole 303, a screw hole 305, a through hole 111, and the groove 127 for receiving a sealing member such as an O-ring.

The plate 301 may be surrounded by the protruding sidewall 123 and may have a concave shape. A portion of the gas flow control device 105 is disposed with the gas inlet 113, which is a path through which an external reaction gas is introduced. At least two screw holes 305 are provided around the gas inlet 113, and a screw, which is a mechanical connecting member connecting the gas flow control device 105 to a gas supply unit 109, passes through the screw hole 305. The other portion of the gas flow control device 105 is provided with the RF rod hole 303, and thus the RF rod 313 connected to an external plasma supply unit (not shown) may be mechanically connected to the gas supply unit 109 below the gas flow control device 105.

The gas supply unit 109 connected to the RF rod 313 may serve as an electrode in a CCP process. In this case, a gas supplied by a gas channel and a gas injection device of the gas supply unit 109 will be activated in a reaction space by the gas supply unit 109 serving as an electrode and injected onto a substrate on the substrate support plate 103.

In some embodiments, the injection hole 133 of the gas supply unit 109 may be distributed over an area greater than or equal to the area of the substrate S to be processed. Although not shown in the drawings, in a further embodiment, the injection hole 133 of the gas supply unit 109 may be distributed over an area having a ring shape corresponding to the shape of the substrate to be processed. By arranging the injection holes 133 as described above, a more intensive process for an edge region of the substrate S to be processed may be achieved. That is, by matching a supply region of a first gas supplied through the injection hole 133 with the edge region (e.g., bevel edge) of the substrate to be processed, selective deposition of the thin film on the edge region of the substrate to be processed may be more easily implemented. Alternatively, such an effect may be achieved by making the density or number of holes in a lower surface of the gas supply unit corresponding to a peripheral portion of the substrate higher or greater than the density or number of holes in the lower surface of the gas supply unit corresponding to an inner portion of the substrate.

The substrate support plate 103 of FIG. 7 may be a modification of the substrate support plate according to the above-described embodiments (e.g., the substrate support plate of FIG. 2). For example, the substrate support plate 103 may include the recess R formed by the first step S1 and the second step S2 and a path formed in the recess R. An upper surface of the second step S2 may be below the upper surface of the substrate support plate in the recess R. In an alternative example, the upper surface of the second step S2 may be below an upper surface of a pad of the substrate support plate. In any case, the second reaction space 125-2 may have a height higher than that of the first reaction space 125-1, and a channel through which the second gas from the path may move may be formed between the upper surface of the second step S2 and a lower surface of the substrate to be processed.

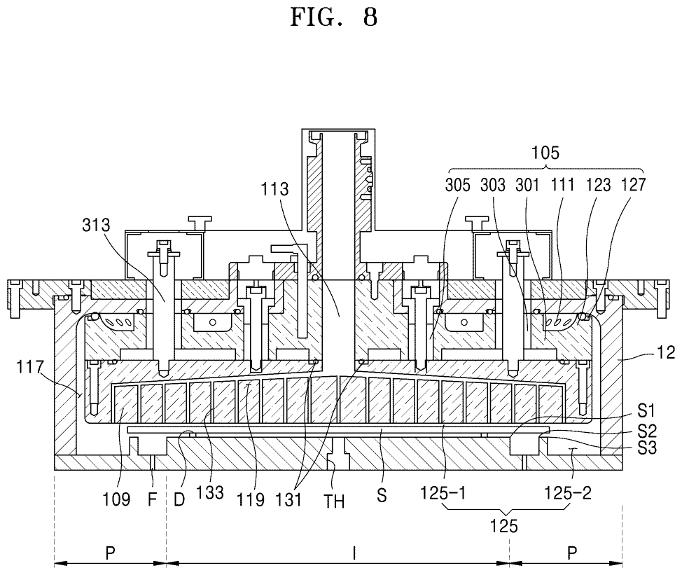

FIG. 8 is a view of a substrate processing apparatus according to embodiments of the inventive concept. The substrate processing apparatus according to the embodiments may be a variation of the substrate processing apparatus according to the above-described embodiments. Hereinafter, repeated descriptions of the embodiments will not be given herein.

Referring to FIG. 8, the substrate support plate 103 may be a modification of the substrate support plate according to the above-described embodiments (e.g., the substrate support plate of FIG. 3). For example, the substrate support plate 103 may include the recess R formed by the first step S1 and the second step S2 and the path F formed in the recess R. In addition, the substrate support plate 103 may further include the third step S3 formed outside the second step S2. The second reaction space 125-2 of the peripheral portion may extend from the upper surface of the substrate support plate outside the third step S3 to the gas supply unit 109.

A protrusion may be formed by the second step S2 and the third step S3. In other words, the substrate support plate may include a protrusion formed between the recess R and the third step S3. An upper surface of the protrusion (i.e., the upper surface of the third step S3) may be disposed to correspond to an edge region of a substrate to be processed. The upper surface of the substrate support plate outside the protrusion may be below the upper surface of the pad of the substrate support plate. Therefore, the height of the second reaction space 125-2 may be greater than the height of the first reaction space 125-1, and more plasma may be generated in the second reaction space 125-2.

In some examples, the upper surface of the third step S3 may be below the upper surface of the substrate support plate in the recess R. In an alternative example, the upper surface of the third step S3 may be below the upper surface of the pad D of the substrate support plate 103. In either example, a channel through which the second gas from the path F may move may be formed between the upper surface of the third step S3 and the lower surface of the substrate S to be processed.

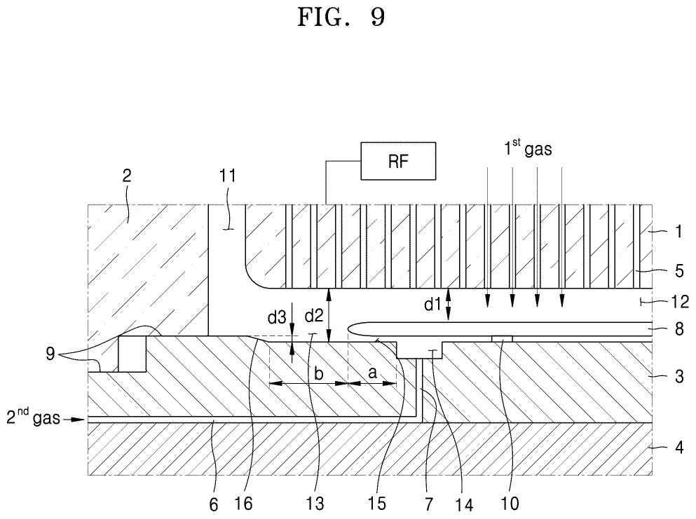

FIG. 9 schematically shows a substrate processing apparatus according to embodiments of the inventive concept. The substrate processing apparatus according to the embodiments may be a variation of the substrate processing apparatus according to the above-described embodiments. Hereinafter, repeated descriptions of the embodiments will not be given herein.

Referring to FIG. 9, a reactor may include a gas supply unit 1, a reactor wall 2, a susceptor 3, and a heating block 4 supporting the susceptor 3. A reaction space may include a first reaction space 12 and a second reaction space 13. The reaction space may be formed by face-contact and face-sealing of a lower surface of the reactor wall 2 and an upper edge of the susceptor 3. A side surface of the reactor wall 2 may form a side surface of the reaction space, a lower surface of the gas supply unit 1 may form an upper surface of the reaction space, and the susceptor 3 may form a lower surface of the reaction space.

The susceptor 3 includes a concave portion and a convex portion, wherein the concave portion may be formed in an inner surface of the susceptor 3, and the diameter of the concave portion may be greater than the diameter of the substrate 8. For example, as shown in FIG. 9, the diameter of the concave portion of the susceptor 3 may be b greater than the diameter of the substrate 8. The convex portion may be formed at the peripheral portion of the susceptor, specifically at the edge of the susceptor on which the substrate is not seated.

The concave portion and the convex portion may be connected to each other by a step 16, and the height of the step 16 may be d3. In an example, a portion of the convex portion of the susceptor may contact the lower surface of the reactor wall 2 to form the side surface of the reaction space. The substrate 8 may be seated on the concave portion of the susceptor 3, that is, the inner portion, and the inner portion of the susceptor may support the substrate 8. The first reaction space 12 may be formed between an upper surface of the substrate 8 on the susceptor 3 and the gas supply unit 1, and may have a distance of d1. The second reaction space 13 may be defined by a bevel edge of the substrate, a concave portion b of the susceptor on which the substrate is not seated, the step 16 of the susceptor 3, and the lower surface of the gas supply unit 1, and may have a distance of d2.

The first gas may be supplied to the first reaction space 12 and the second reaction space through a first gas inlet 5 of the gas supply unit 1. The second gas may be supplied to the second reaction space 13 below the bevel edge of the substrate through the second gas inlet 6 and a third gas inlet 7 formed in the susceptor 3. The first gas may include a reaction gas, for example, a source gas (e.g. precursor vapor) containing a raw material component of the thin film. The first gas may be supplied to the reaction space by a carrier gas. The carrier gas may be inert gas or another reactive gas, such as oxygen or nitrogen, or mixtures thereof, including a raw material component of the thin film.

The second gas may be a filling gas filled in an outer chamber (not shown) on which the reactor is mounted. In an embodiment, the second gas may be an inert gas, an oxygen gas, or a mixture thereof. The second gas may be supplied to the second reaction space 13 through the second gas inlet 6 and the third gas inlet 7.

In FIG. 9, a buffer space 14 is formed in the concave portion of the susceptor 3 below the substrate 8. The second gas supplied through the second gas inlet 6 and the third gas inlet 7 may form a gas barrier in region a between a lower edge of the substrate 8 and the second reaction space 13 while filling the buffer space 14. Therefore, the source gas supplied to the first reaction space 12 and the second reaction space 13 may be prevented from flowing into a lower portion of the substrate. The gas barrier may be formed in a gap 15 between the lower edge of the substrate 8 and the susceptor.

In FIG. 9, the substrate 8 may be loaded onto a substrate support pad 10 of the inner portion of the susceptor 3. The susceptor according to the prior art has a concave pocket structure to prevent sliding when loading the substrate and allows the substrate to be seated into the pocket of the susceptor. However, in the disclosure, for the processing of the edge portion of the substrate, the susceptor does not have a pocket structure, and a substrate support plate is configured such that the edge portion of the substrate is exposed to the second reaction space 125-2. In this case, the substrate support pad 10 may prevent the substrate 8 from sliding by a gas pocket between the rear surface of the substrate and the susceptor when the substrate 8 is seated on the susceptor 3. That is, by introducing the substrate support pad 10, when the substrate 8 is seated on the susceptor 3, a cushioning effect of sliding the substrate on the substrate support plate when gas remaining between the rear surface of the substrate and the susceptor exits may be prevented.

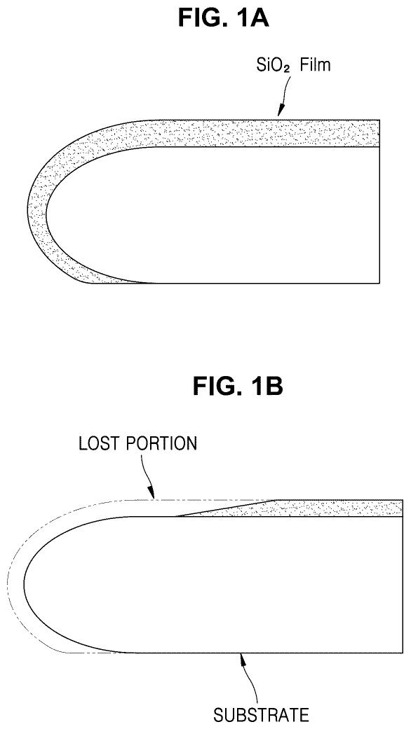

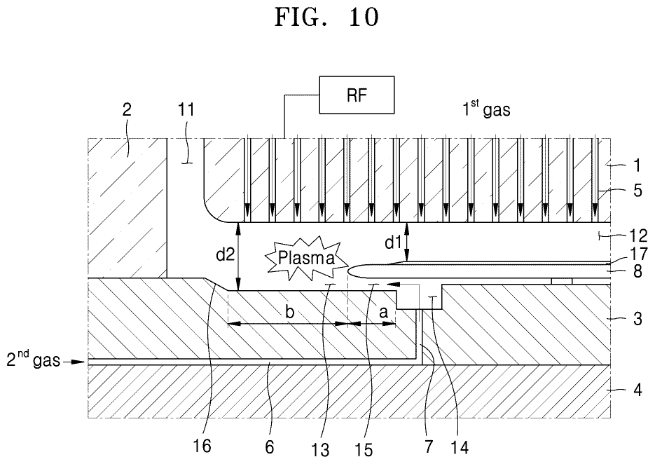

FIG. 10 is a partial enlarged view of the substrate processing apparatus of FIG. 9. Referring to FIG. 10, the substrate 8 on which the thin film 17 is deposited is seated on the susceptor 3. The substrate is subjected to a subsequent process after the thin film is deposited. For example, after a chemical mechanical polishing (CMP) process, a thin film on a bevel edge of a substrate edge is lost (see FIG. 1). Accordingly, FIG. 10 illustrates a part of a process of depositing a thin film on the bevel edge again. In FIG. 10, a source gas including components of a thin film as a first gas and a reaction gas such as a silicon-containing gas and an oxygen gas are supplied to the first reaction space 12 and the second reaction space 13 through the gas supply unit 1 and the first gas inlet 5. At the same time, a second gas is supplied into the buffer space 14 between a lower surface of the substrate and the susceptor 3 through the second gas inlet 6 and the third gas inlet 7, and a gas barrier is formed between a lower surface of the bevel edge of the substrate and the susceptor 15. Therefore, the source gas supplied to the first reaction space 12 and the second reaction space 13 is prevented from flowing into the lower portion of the substrate.

As a next operation, the source gas and the reaction gas introduced into the reaction space are activated by applying RF power to the gas supply unit 1. Here, the thin film is deposited only on the bevel edge of the substrate edge by preventing the generation of plasma in the first reaction space 12 and generating plasma in the second reaction space 13. To this end, a distance d1 of the first reaction space 12 may be maintained at a narrow interval so that no plasma may be generated, and a distance d2 of the second reaction space 13 may be maintained at an interval that allows plasma to be generated.

For example, d1 may be preferably 2 mm or less, and d2 may be preferably 3 mm or more. According to Paschen's law, plasma generation is determined by pressure p and a distance d in the reaction space. That is, when the pressure in the reaction space is constant, in the short distance reaction space, a mean free path of gas molecules is short, so the probability of collision between gas molecules is low and ionization is difficult. In addition, since the acceleration distance is short, the discharge is difficult, and thus plasma is hardly generated. In general, when the reaction space is about 2 mm or less, plasma generation is difficult. For example, in FIG. 10, a distance between an electrode (shower head) and the substrate in the reaction space on the substrate, that is, the first reaction space 12 may be 1 mm or less. In this case, plasma generation is difficult even when a gas and an RF electrode are supplied. However, in the second reaction space 13 where a bevel edge of a substrate edge is located, a distance between the susceptor 3 and the electrode may be 2 mm or more, and thus plasma generation is possible. Thus, this reactor structure allows for selective processing (e.g., deposition) in the bevel edge of the substrate.

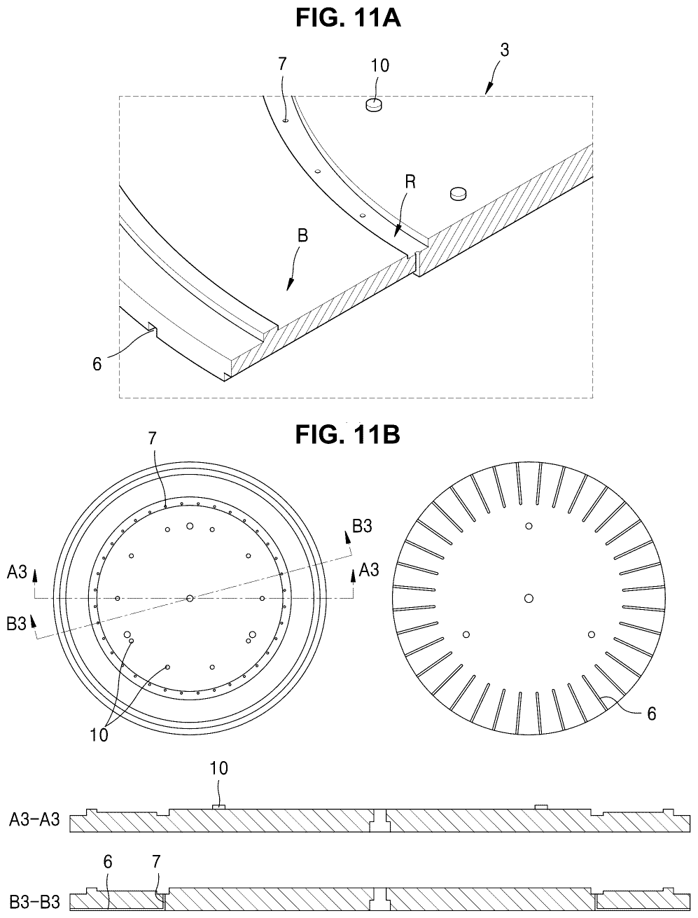

FIG. 11 is a detailed view of the susceptor 3 according to FIG. 10.

Referring to FIG. 11A, the substrate support pad 10 may have a height of 0.5 mm, and a plurality of substrate support pads 10 may be arranged at equal intervals based on the center of the susceptor 3. For example, ten substrate support pads 10 may be arranged at 36 degree intervals. In FIG. 11A, a plurality of first gas inlets 6 are formed on the lower surface of the susceptor. As shown in FIG. 11B, the first gas inlets 6 may be arranged at equal intervals around the center of the susceptor. For example, 36 first gas inlets 6 may be arranged at 10 degree intervals. The first gas inlet may form a gas inlet path together with an upper surface of a heating block (not shown) supporting the susceptor.

In addition, in FIG. 11A, a plurality of second gas inlets 7 may vertically penetrate region R of the susceptor to communicate with the first gas inlets 6. Therefore, a second gas may be supplied to the region R through the first gas inlet 6 and the second gas inlet 7. Region R may form the buffer space 14 (of FIG. 10) together with the lower portion of the substrate. Region B of FIG. 11 forms the second reaction space 13 (of FIG. 10) together with the gas supply unit and the reactor wall.

FIG. 12 schematically shows a substrate processing apparatus according to embodiments of the inventive concept. The substrate processing apparatus according to the embodiments may be a variation of the substrate processing apparatus according to the above-described embodiments. Hereinafter, repeated descriptions of the embodiments will not be given herein.

Referring to FIG. 12, a protrusion 18 is on the susceptor 3, and a buffer space 14 and the second reaction space 13 are formed between the protrusion 18 and the susceptor 3. The protrusion 18 faces the lower surface of a bevel edge of a substrate edge. Compared with the substrate processing apparatus according to the embodiment of FIG. 10, in the substrate processing apparatus according to the embodiment of FIG. 12, the distance 15 between the protrusion 18 and the substrate has a narrower structure. This may further enhance a blocking effect of the gas barrier (blocking the inflow of gas into the first and second reaction spaces 125-1 and 125-2 formed between the protrusion 18 and the substrate 8. Therefore, the technical effect of more effectively preventing the thin film deposition on a lower portion of a bevel edge of the substrate may be achieved. The distance 15 between the protrusion 18 and the substrate 8 may be equal to or less than the height of the substrate support pad 10.

As described above, the distance d1 of the first reaction space 12 may be within about 2 mm, and thus plasma generation is difficult in the first reaction space 12. Meanwhile, the distance d2 of the second reaction space 13 may be about 3 mm or more, and thus plasma is easily generated in the second reaction space 13. By changing a physical structure in the reaction space in this manner, the technical effect of properly controlling plasma generation locally in the reaction space may be achieved.

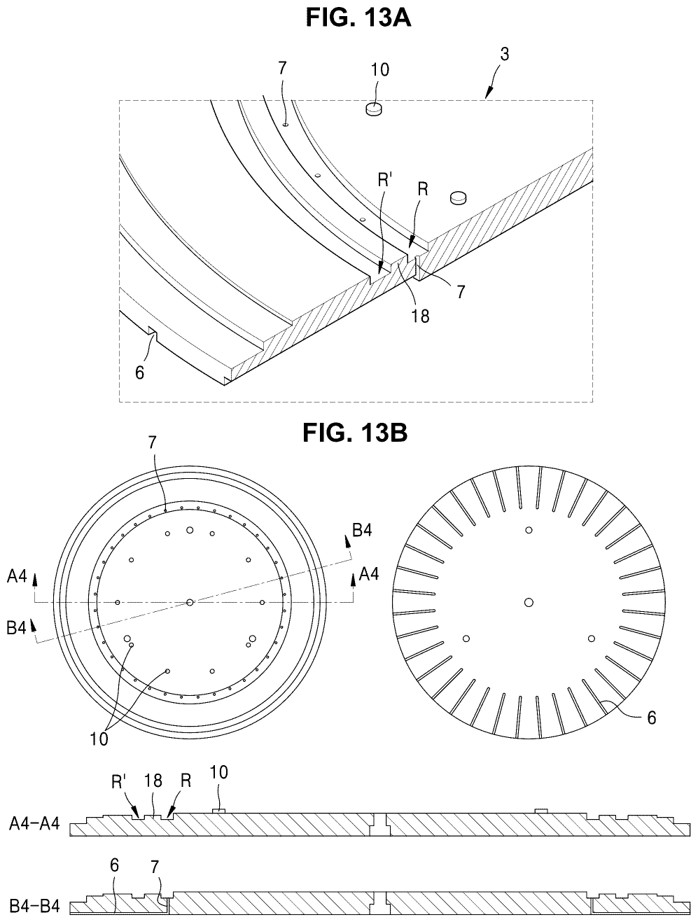

FIG. 13 is an oblique cross-sectional view of the susceptor of FIG. 12. The region R of FIG. 13A may form the buffer space 14 (of FIG. 12) together with the lower surface of a bevel edge of the substrate. Region R′ also forms the second reaction space 13 (in FIG. 12) together with a reactor wall and a lower surface of a gas supply unit. Since the second gas inlet 6 and the third gas inlet 7 are the same as those of FIG. 11, a description thereof will not be given herein.

According to the substrate processing apparatus according to the embodiments described above, symmetric bevel deposition of the same width is possible on the substrate, regardless of the position of the substrate 8 on the susceptor 3. That is, symmetric bevel deposition of the same width is possible along a bevel edge of a substrate edge, regardless of the alignment position of the substrate 8 on the susceptor 3.

In more detail, since the lower surface of the gas supply unit 1, that is, the surface facing the substrate, is flat without bending, the distance d1 between the upper surface of the substrate 8 defining the first reaction space 125-1 and the lower surface of the gas supply unit 1 may be constant. Therefore, regardless of the alignment state of the substrate, no plasma is generated in the first reaction space 12 and no thin film is deposited on the upper surface of the substrate. Meanwhile, since plasma is generated in the second reaction space 13 adjacent to the bevel edge of the substrate, symmetrical bevel edge film deposition of the same width is possible along the bevel edge of the substrate edge. In other words, since the thin film deposition on the bevel edge of the substrate is caused by the second reaction space 13 in contact with the bevel edge of the substrate, irrespective of the alignment state of the substrate on the susceptor 3 in the first reaction space 12, the symmetric bevel deposition of uniform width is possible.

FIG. 14 schematically shows a substrate processing apparatus according to embodiments of the inventive concept. The substrate processing apparatus according to the embodiments may be a variation of the substrate processing apparatus according to the above-described embodiments. Hereinafter, repeated descriptions of the embodiments will not be given herein.

Referring to FIG. 14, a stepped structure may be implemented at the edge of the gas supply unit 1. The stepped structure may perform a function of generating plasma at the edge of the substrate 8. The stepped structure may contribute to thin film deposition on a bevel edge of the substrate 8. However, due to the stepped structure of a portion of the lower surface of the gas supply unit 1, a distance between an upper surface of the substrate 8 and the gas supply unit 1 may vary depending on an alignment state of the substrate 8. Since the change in the distance between the substrate 8 and the gas supply unit 8 affects the generation of plasma, the symmetry of a deposition film on the bevel edge may be determined according to the alignment state of the substrate 8 on the susceptor 3.

When there is a step in a portion of the gas supply unit 1, the distance between the substrate 8 and the gas supply unit 1 may be different for each point of the substrate depending on the alignment state of the substrate 8 on the susceptor 8, and the width of the film deposited on the bevel edge may be different for each point on the substrate. For example, the substrate 8 may be aligned on the susceptor 8 such that one end of the substrate 8 is in a step region of the second reaction space 12 and the other end of the substrate 8 is in the first reaction space 12. In this case, one surface of the bevel edge of the substrate is deposited, while the opposite surface of the bevel edge of the substrate may not be deposited, in which case the symmetry of the deposition film on the bevel edge may be destroyed. Therefore, in the case of FIG. 14, alignment of the substrate on the susceptor becomes an important factor for uniform and symmetrical bevel deposition.

TABLE 1

| Process condition | | Condition 1 | Condition 2 |
|---|---|---|---|
| Substrate temp (° C.) | | 100 | 100 |
| Time (sec) | Source feeding | 10~80 | 10~80 |
| | RF plasma | 10~80 | 10~80 |
| first gas | Purge Ar | 200~1000 | 200~1000 |
| flow rate | Carrier Ar | 100~500 | 100~500 |
| (sccm) | O2 | | 50~200 |
| second gas | Filling gas | 100~500 (O2) | 100~500 (Ar) |
| flow rate | | | |
| (sccm) | | | |
| RF Power (W) | | 400~1200 | 400~1200 |
| Pressure (Torr) | Reactor | 1~10 | 1~10 |
| | Outer Chamber | | |

| | | |
|---|---|---|
| Cycle | 1 | 1 |

Table 1 above shows bevel deposition process conditions according to the disclosure. The following evaluation is performed by a PECVD method at a substrate temperature of 100° C., and proceeds in two ways, a first process condition and a second process condition. In the first process condition, a silicon source and carrier Ar are used as a first gas and oxygen is used as a second gas. As described above, the first gas is supplied to the first reaction space 125-1 through a first inlet of the gas supply unit, and the second gas, which is a filling gas of an outer chamber surrounding a reaction gas, is supplied to a lower space of a substrate edge through second gas inlet and third gas inlet formed in a susceptor.

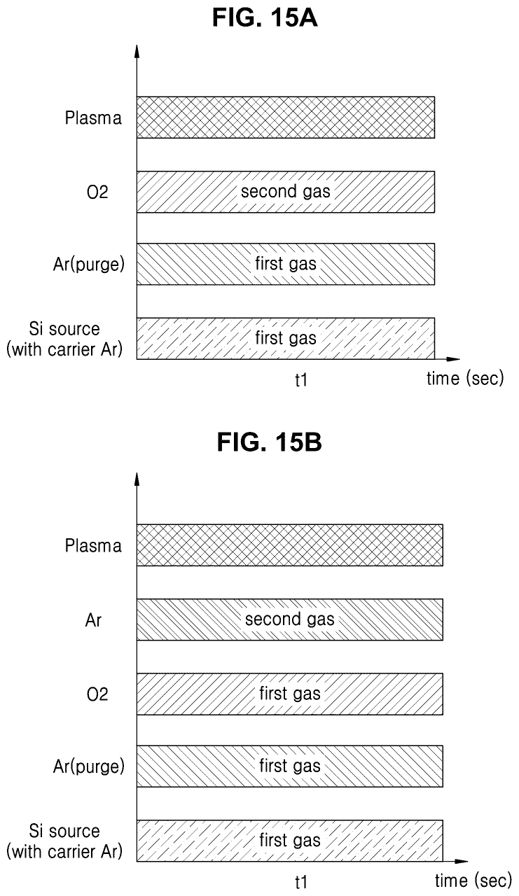

FIG. 15 shows a PECVD process. FIG. 15A is a first process condition in which an oxygen gas is supplied as a second gas (filling gas). FIG. 15B is a second process condition in which an Ar gas is supplied as a second gas (filling gas). A running time t1 of the gas supply is about 10 seconds to 80 seconds and is repeated at least once. While the second gas is supplied, the first gas is supplied and plasma is simultaneously applied.

According to some embodiments, under the first process condition, as shown in FIG. 15A, the silicon source gas as the first gas may be supplied through the gas supply unit 109, and the oxygen gas as the second gas may be supplied through a path. Plasma may be applied with the gas supply, in which case the oxygen gas supplied through the path may be ionized and react with the silicon source gas to form a thin film on a substrate. Since the generation of plasma in the first reaction space 125-1 is suppressed as described above, the thin film will be formed on the edge region of the substrate.

According to another embodiment, under the second process condition, as shown in FIG. 15b, the silicon source gas as the first gas may be supplied through the gas supply unit 109, and an inert gas such as argon may be supplied through the path as the second gas. Plasma may be applied along with the gas supply, in which case the oxygen gas supplied through the gas supply unit 109 may be ionized and react with the silicon source gas to form a thin film on the edge region of the substrate.

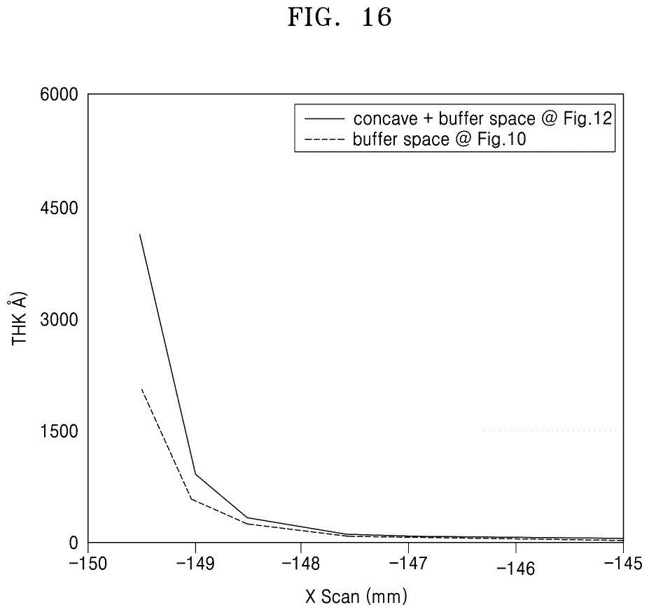

FIG. 16 shows a thickness of a SiO₂ thin film deposited on a bevel edge of a substrate when applying the second process condition. In particular, the thickness of the SiO₂ thin film deposited on the bevel edge is shown in a region from the edge of a silicon substrate having a diameter of 300 mm to 5 mm, that is, an area of 145 mm to 150 mm of an X scan area.

Referring to FIG. 16, compared to the thickness of the thin film formed when there is only the buffer space 14 (of FIG. 10), it can be seen that when the protrusion 18 (of FIG. 12) and the buffer space 14 (of FIG. 12) are together, that is, when the second reaction space 13 (of FIG. 12) is formed by the protrusion 18 (of FIG. 12), the thin film is further deposited on the bevel edge of the a substrate edge. In addition, the evaluation results show that in both cases, thin film deposition is not substantially performed at the center portion of the substrate (i.e., an area of 0 mm to 145 mm of the X scan area).

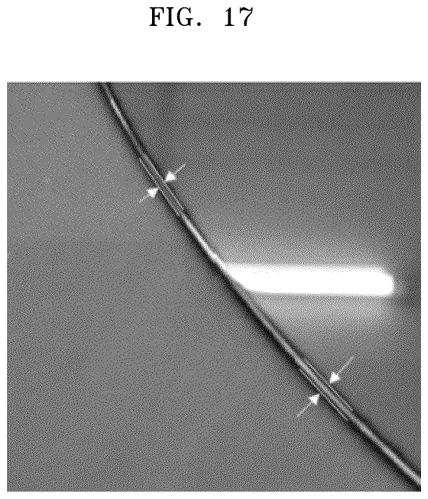

FIG. 17 shows a photograph of a film deposited in a 1 mm area of a bevel edge of an actual substrate edge. As illustrated in FIGS. 16 and 17, when depositing a thin film on the bevel edge of the substrate using a substrate processing apparatus according to embodiments of the inventive concept, the thin film may be deposited intensively in an area of 149 mm to 150 mm of the X scan area. With this thin film deposited selectively on the edge region of the substrate, the adhesion between substrates may be increased to achieve smooth substrate stacking.

It is to be understood that the shape of each portion of the accompanying drawings is illustrative for a clear understanding of the disclosure. It should be noted that the portions may be modified into various shapes other than the shapes shown.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A substrate processing apparatus comprising a substrate support plate configured to support a substrate to be processed, the substrate support plate comprising:
an inner portion having an upper surface with an area less than an area of the substrate to be processed;
a first step formed by a side surface of the inner portion;
a second step surrounding the first step;
a recess formed by the first step and the second step; and
a third step formed outside the recess,
wherein at least one path is formed on an upper surface of the substrate support plate between the first step and the second step, and wherein the at least one path is formed in the recess.

2. The substrate processing apparatus of claim 1, wherein a distance from the center of the substrate support plate to the second step is less than the radius of the substrate to be processed.

3. The substrate processing apparatus of claim 1, further comprising a recess formed by the first step and the second step,
wherein the at least one path is formed in the recess.

4. The substrate processing apparatus of claim 1, wherein at least a portion of the upper surface of the substrate support plate outside the at least one path is disposed below the upper surface of the inner portion.

5. The substrate processing apparatus of claim 4, wherein an upper surface of the second step outside the at least one path is disposed below an upper surface of the first step inside the at least one path.

6. The substrate processing apparatus of claim 4, further comprising a third step formed outside the second step,
wherein a lower surface of the third step is disposed below the upper surface of the inner portion.

7. The substrate processing apparatus of claim 1, wherein plasma is generated by supplying power between the gas supply unit and the substrate support plate, and wherein, during the supplying power between the gas supply unit and the substrate support plate, generation of plasma is suppressed in a first distance between the gas supply unit and the substrate while plasma is formed in a second distance between the gas supply unit and the second step of the substrate support plate, the second distance being larger than the first distance.

8. The substrate processing apparatus of claim 1, wherein the gas supply unit comprises an electrode surface directly facing the inner portion of the substrate support plate, the electrode surface extending from a center lower surface of the gas supply unit to an edge lower surface of the gas supply unit.

9. A substrate processing apparatus comprising:
a substrate support plate comprising a recess and at least one path formed in the recess;
a gas supply unit on the substrate support plate; and
a reaction space formed between the substrate support plate and the gas supply unit, wherein the reaction space comprises:
a first reaction space between the gas supply unit and a portion of the substrate support plate inside the recess; and
a second reaction space between the gas supply unit and the other portion of the substrate support plate outside the recess,
wherein a first distance between the gas supply unit and a portion of the substrate support plate inside the recess is less than a second distance between the gas supply unit and the other portion of the substrate support plate outside the recess,
wherein the substrate support plate further comprises a third step formed outside the recess, and
wherein the second reaction space extends from an upper surface of the substrate support plate outside the third step to the gas supply unit.

10. The substrate processing apparatus of claim 9, wherein the substrate support plate further comprises a protrusion formed between the recess and the third step.

11. The substrate processing apparatus of claim 9, wherein an upper surface of the third step is disposed to correspond to an edge region of the substrate to be processed.

12. The substrate processing apparatus of claim 9, wherein the substrate support plate further comprises at least one pad disposed on the upper surface of the substrate support plate inside the recess, and wherein an upper surface of the third step is disposed below an upper surface of the at least one pad.

13. The substrate processing apparatus of claim 9, wherein
the gas supply unit comprises a step, and
the second reaction space extends from the upper surface of the substrate support plate outside the recess to the step of the gas supply unit.

14. The substrate processing apparatus of claim 9, wherein
the gas supply unit comprises a plurality of injection holes, and
the plurality of injection holes are distributed over at least the area of an upper surface of the substrate support plate or more extending from the center of the substrate support plate to the recess.

15. The substrate processing apparatus of claim 9, wherein the plurality of injection holes are distributed over at least the area of the substrate to be processed or more.

16. The substrate processing apparatus of claim 9, wherein the substrate processing apparatus is configured to supply a first gas through the gas supply unit and to supply a second gas different from the first gas through the at least one path.

17. The substrate processing apparatus of claim 9, wherein plasma is generated by supplying power between the gas supply unit and the substrate support plate, and
plasma of the first reaction space is less than plasma of the second reaction space.

18. The substrate processing apparatus of claim 9, wherein an upper surface of the substrate support plate outside the recess is below an upper surface of the substrate support plate inside the recess, and wherein the second reaction space extends from the upper surface of the substrate support plate outside the recess to the gas supply unit.

19. The substrate processing apparatus of claim 9, wherein plasma is generated by supplying power between the gas supply unit and the substrate support plate,
wherein, during the supplying power between the gas supply unit and the substrate support plate, a first plasma is formed in the first distance and a second plasma is formed in the second distance, and
wherein the first plasma in the first distance is less than the second plasma un the second distance by Paschen's law.

20. The substrate processing apparatus of claim 9, the gas supply unit comprising an electrode surface directly facing the substrate support plate, the electrode surface extending from a middle lower surface of the gas supply unit to an edge lower surface of the gas supply unit.
